(19) United States
(12) Patent Application Publication
(10) Pub. No.: US 2012/0329203 A1
(43) Pub. Date: Dec. 27, 2012

(54) Method for Forming Silicon Thin Film

(76) Inventors: LIANG-TUNG CHANG, Miaoli County (TW); Tzu-Heng Chang, Miaoli County (TW)

(21) Appl. No.: 13/166,352

(22) Filed: Jun. 22, 2011

(51) Int. Cl. H01L 31/18; H01L 21/20

(52) U.S. Cl. 438/87; 438/89; 438/478; 257/E31.039; 257/E21.09

(57) ABSTRACT

The present invention is to provide a method of creating a PIN silicon thin film comprising the steps of providing a molten P-type, Intrinsic and N-type semiconductor material. Next, it is performing a down draw process or a casting process of the molten P-type. Intrinsic and N-type semiconductor material. Then, it is selectively performing a dual-side rolling process to create a P-type, Intrinsic and N-type semiconductor ribbon. Subsequently, it is performing a step of joining the P-type, Intrinsic and N-type semiconductor ribbon to form a PIN semiconductor ribbon. Finally, it is performing a roll press process or a pressing process to the PIN semiconductor ribbon to create the PIN semiconductor thin film.

### FIELD OF THE INVENTION

The present invention relates generally to methods of a silicon sheet fabrication, and more specifically to a roll press method of creating a silicon thin film for electric elements.

### BACKGROUND OF THE INVENTION

Mainly un-satisfied quality silicon for semiconductor use has been previously utilized as the silicon for the solar cells or semiconductor devices. From these, so-called metal melting process, where the reaction between molten zinc and silicon tetra-chloride is performed, is known for the independent supply of silicon, but has the problems of products having powdery and complicated treatment, difficulty of impurity treatments and also the difficulty of casting, which will result high cost, so the process has not been utilized.

To dissolve the problems, silicon production process by gas phase zinc reducing process was proposed, but together with the silicon produce, about ten times of amount of zinc chloride (ZnCl₂) is co-produced and the disposal of it must be troublesome, so the commercial application of this process is very limited. From the point of view of reuse of zinc chloride, the objective has been established, but actually produced silicon is mixture of molten zinc and silicon itself became fine powders, so formed silicon particle having big surface area, then purification became difficult, which was big problem.

To obtain single crystal silicon from poly-crystalline or powdered silicon obtained under these processes, it must have less problem when those silicon poly-crystalline materials having rather big particle size and relatively small surface area are used, because those materials have less absorption of impurities and oxygen, but in the case of silicon being fine powder and having high surface area, removal of surface absorbed materials is required before installing to the crystal growing processes though such silicone bulk is very pure because the absorbed materials must be caused of impurity, which gives complicated procedure and requires treatment of abolishes. Then the producing cost must become high. And according to the normal process, complicated processes of high temperature treatment being applied at first to produce silicon powder or fine crystalline, then cooling and then heating to melt are required, and which requires repeating heating/cooling, which gives also troublesome from the energy consumption.

As shown in the above, previous technologies are all mainly aimed silicon to grown as solid or crystalline, so the formed crystal blocks or powder is considered to be exposed in air where once formed silicon is re-refined according to the requirement, then re-melt or crystallization is performed, when in grown single crystals or grown poly-crystalline, where at least excess energy is required for re-melting. And when in producing silicon blocks or powders, as the materials, is premised to expose in air, block silicon is preferred to minimize the impurity absorption when in producing silicon raw material, then reducing process of silicon tetra-chloride by zinc, which is the simplest way of producing silicon, could not be applied in the commercial process, which has also big problem. Recently, some trials of direct taking out of molten silicon from the reaction furnace is performed, but several problems such as corrosion by co-product hydrochloric acid and reaction between furnace wall and silicon, which gives shortening of furnace life, due to high operation temperature, have been arisen.

Based-on the above description, the present invention provides a method of creating a silicon thin film roll that can simultaneously highly reduce production cost and manufacturing cost.

### SUMMARY OF THE INVENTION

One objective of the present invention is to provide a method of creating a PIN or PN semiconductor thin film roll with three type molten semiconductor materials. These PIN or PN semiconductor thin films are suitable for electric elements.

In order to achieve the objectives, the present invention is to provide a method of creating a PIN semiconductor thin film. The method comprises the steps of providing a molten P-type semiconductor material, a molten Intrinsic semiconductor material and a molten N-type semiconductor material. Next, it is performing a down draw process or a casting process of the molten P-type semiconductor material, the molten intrinsic semiconductor material and the molten N-type semiconductor material. Then, it is selectively performing a dual-side rolling process to the molten P-type semiconductor material, the molten Intrinsic semiconductor material and the molten N-type semiconductor material to create a P-type semiconductor ribbon, a Intrinsic semiconductor ribbon and a N-type semiconductor ribbon. Subsequently, it is performing a step of joining the P-type semiconductor ribbon, the Intrinsic semiconductor ribbon and the N-type semiconductor ribbon to form a PIN semiconductor ribbon. It is performing a step of roll press process to the PIN semiconductor ribbon to create the PIN semiconductor thin film.

The down draw process is made by selectively injecting the molten P-type semiconductor material, the molten Intrinsic semiconductor material and the molten N-type semiconductor material into their corresponding collection troughs and downward flowing out along their corresponding orifices, respectively. The dual-side rolling process is performed by dual-side rollers. The joining step may be performed by a set of alignment module established by XYθ stage and vision technology.

The method further comprising a step of performing a winging process of the PIN semiconductor thin film such that the PIN semiconductor thin film roll is created thereby.

According to an aspect of the present invention, a method of creating a semiconductor thin film, comprising the steps of providing a molten semiconductor material. Next, it is performing a down draw process or a casting process of the molten semiconductor material to create a semiconductor ribbon. Then, it is performing a roll press process or a pressing process to the semiconductor ribbon to create a semiconductor thin film. Subsequently, it is performing an ion implanting process of the semiconductor thin film to form a N or P type semiconductor thin film as traditional silicon fab process.

According to another aspect of the present invention, a method of creating a PN semiconductor thin film is provided which may referred to the method of creating the PIN semiconductor thin film.

### BRIEF DESCRIPTION OF THE DRAWINGS

FIG. 1 is an exemplary fusion down draw process for forming a silicon sheet.

FIG. 2 is another exemplary down draw process for forming a silicon sheet.

FIG. 3 is an exemplary down draw process for forming a PIN silicon thin film according to the present invention.

FIG. 4 is an exemplary down draw process for forming a PN silicon thin film according to the present invention.

FIG. 5 is an exemplary down draw process for forming a P-type or N-type silicon thin film according to the present invention.

FIG. 6 shows a roll press process for forming a silicon thin film roll according to the present invention.

### DETAILED DESCRIPTION OF THE PREFERRED EMBODIMENT

The present invention and embodiments are now described in detail. In the diagrams and descriptions below, the same symbols are utilized to represent the same or similar elements. The possible embodiments of the present invention are described in illustrations. Additionally, all elements of the drawings are not depicted in proportional sizes but in relative sizes.

In accordance with embodiments of the present invention, systems and methods for determining the shape of silicon sheets during and/or after the forming process are described. As used herein, the term “silicon sheet” is intended to include silicon during or after its formation, without limitation. Thus, as one example, the term “silicon sheet” can include a silicon ribbon downstream from the root of an isopipe in its various states (e.g., visco-elastic, elastic, etc.), as well as the final silicon sheet that may be cut from the silicon ribbon.

While described herein with reference to the fusion down draw process, it is contemplated that the systems and methods described herein can be used to determine the shape of silicon ribbons or sheets formed using any of various known silicon forming processes, including float processes, slot draw processes, up draw processes, and single-sided overflow down draw processes.

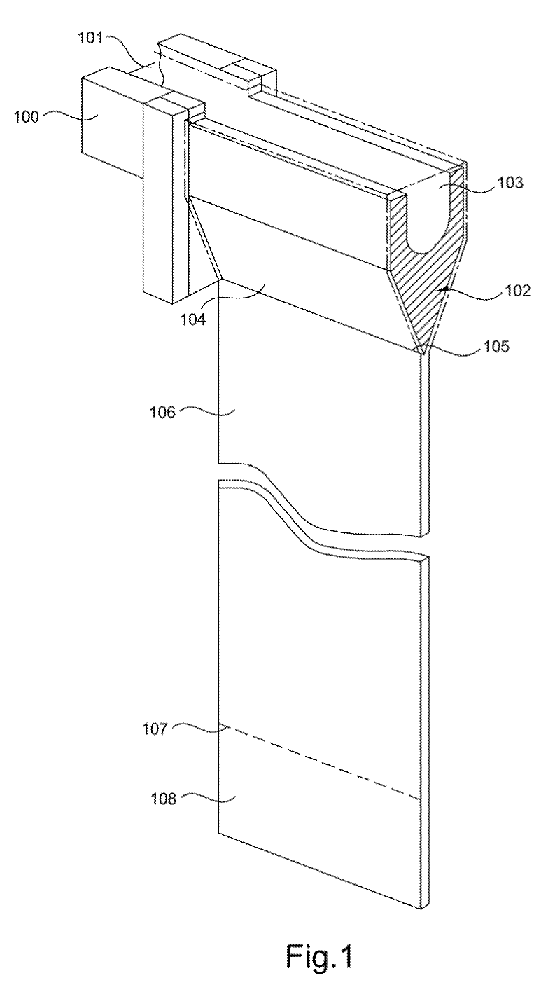

Referring to FIG. 1, it is an exemplary fusion down draw process for forming a silicon sheet, which a supply pipe 100 provides molten silicon 101 to a refractory body, or isopipe, 102, comprising a collection trough 103. The molten silicon overflows the top of the collection trough 103 on both sides to form two separate streams of silicon that flow downward and then inward along converging outer surfaces 104 of the isopipe 102 that join at a draw line or root 105 of the isopipe 102. The two molten silicon streams meet at the root, where they fuse together into a single silicon ribbon 106. The silicon ribbon 106 can then be fed to drawing and other downstream processing equipment from which a silicon sheet may finally results.

Silicon ribbon passes through several physical states during the forming process. The molten silicon overflows the sides of the isopipe 102 in a viscous state. The separate flows then fuse to form a silicon ribbon at the bottom of the isopipe 102, after which the silicon of the ribbon transitions from a visco-elastic state, to an elastic state. After the silicon has transformed into an elastic material, the silicon ribbon 106 can be scored and separated, such as illustrated by dash line 107, to form the final silicon sheet or silicon panel 108.

In some embodiments, the shape of the silicon may be determined for a moving ribbon of silicon, such as across the width of the ribbon. For example, the shape of a moving silicon ribbon being drawn from an isopipe in a fusion downdraw process can be determined across a width of the sheet at a given location, such as in the elastic region of the silicon. In a typical manufacturing environment, the fusion draw machine is an enclosed space that may reach a high temperature (e.g. 800.degree. C.), and access to the space is limited to preserve the delicate temperature balance necessary within the confines of the space surrounding the silicon ribbon. Thus, it may be necessary to direct the light source through a window into the space to irradiate the silicon ribbon. In such instances, a one-dimensional scan across the width of the ribbon may be the only practical option. In other embodiments, where access is less limited, a two dimensional measurement can be made, where the ribbon is scanned by the light source both across a plurality of points over the width of the ribbon and down the length of the ribbon in order to acquire a two dimensional shape and/or tilt. In a further aspect, the system can also scan a cut silicon sheet in two dimensions to determine its overall shape and ensure that it meets any required specifications.

Advantageously, the present invention may be used to measure the shape of a silicon having a temperature anywhere below a temperature at which the silicon ceases to have a defined shape (e.g. molten). For example, testing has shown the present invention to be applicable to shape measurement of silicon having a temperature in excess of 800.degree. C. On the other hand, shape measurement of silicon sheets at temperatures at or below room temperature may easily be made. Thus, there are a broad range of possible temperatures for the article being measured, based on the physical limitations of the material itself.

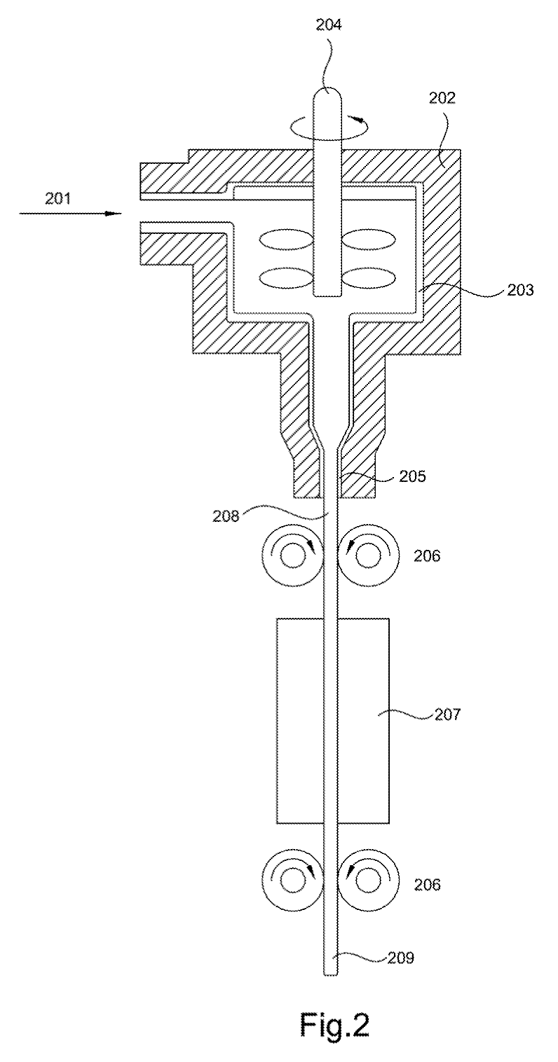

Referring to FIG. 2, it is another exemplary down draw process for forming a silicon sheet, wherein a supply pipe 202 provides molten silicon 201 to a collection trough 203. The molten silicon 201 flows into the collection trough 203 and then downward flowing along an orifice 205 while stirring by a stirrer 204 within the collection trough 203. Silicon ribbon 208 down-draw from the orifice 205 passes through several physical states during the forming process, such as the silicon ribbon transitions from a visco-elastic state to an elastic state. After the silicon has transformed into an elastic material, the silicon ribbon 208 can employ a dual-side rolling process to form the final silicon sheet or silicon plate 209. In the dual-side rolling process, the silicon ribbon 208 passes through dual-side rollers 206 (clockwise and counterclockwise rolling, respectively) for controlling thickness and uniformity of the silicon ribbon, and an annealing furnace used to heat silicon material at a high temperature to change its hardness and strength properties. Annealing process may produce a more uniform, or homogeneous, internal structure.

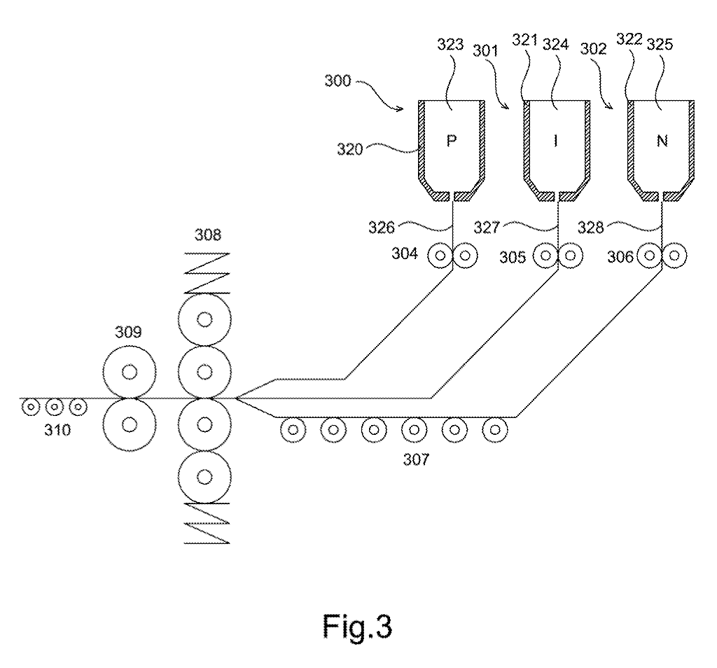

Referring to FIG. 3, it is an exemplary down draw process for forming a PIN semiconductor thin film. For example, the semiconductor comprises silicon or compound semiconductor, for example GaAs. In this embodiment, the semiconductor is for example silicon. Firstly, it prepares a first container 300 with a first collection trough 320 providing molten P-type silicon 323, a second container 301 with a second collection trough 321 providing molten Intrinsic silicon 324 and a third container 302 with a third collection trough 322 providing molten N-type silicon 325. The above mentioned containers may be a supply pipe, such as supply pipe of FIG. 1 or FIG. 2, without limitation. Next, it is performing a down draw process, which is made by the molten P-type silicon 323, the molten Intrinsic silicon 324 and the molten N-type silicon 325 flowing (injecting) into the collection troughs 320, 321 and 322, respectively, and then downward flowing out along their corresponding orifices. In this step, it may be stirred by a stirrer within the collection trough for uniformally mixing it up. In addition, an anneal process may be applied for grain growth. In one embodiment, three-type molten silicon down-draw from the orifices passes through several physical states during the forming process, wherein the three-type molten silicon transitions from a visco-elastic state to an elastic state. After the molten silicon has transformed into an elastic material, silicon ribbons 326, 327 and 328 are then formed, and followed by employing a dual-side rolling process by dual-side rollers 304, 305 and 306, respectively (clockwise and counterclockwise rolling, respectively) for controlling thickness and uniformity of the silicon ribbons 326, 327 and 328. The silicon ribbons 326, 327 and 328 may pass over single side roller 307 for transporting continuously. Subsequently, it can use a set of alignment module, such as establishing by XYθ stage and vision technology, for aligning and attaching or joining flexible silicon ribbons 326, 327 and 328 with each others, and followed by suitably pressing by a roll press 308 to form a stack PIN silicon ribbon, for example forming at a temperature near the melting point. In one embodiment. PIN semiconductor thin film has an energy band for facilitating absorbing solar rays. Next, dual-side roller 309 may be applied for further uniform and completely sealing the PIN silicon ribbon. Every individual roller needs to control roll speed and conveying speed and tension. Similarly, the PIN silicon ribbon may pass over single side roller 310 for transporting continuously.

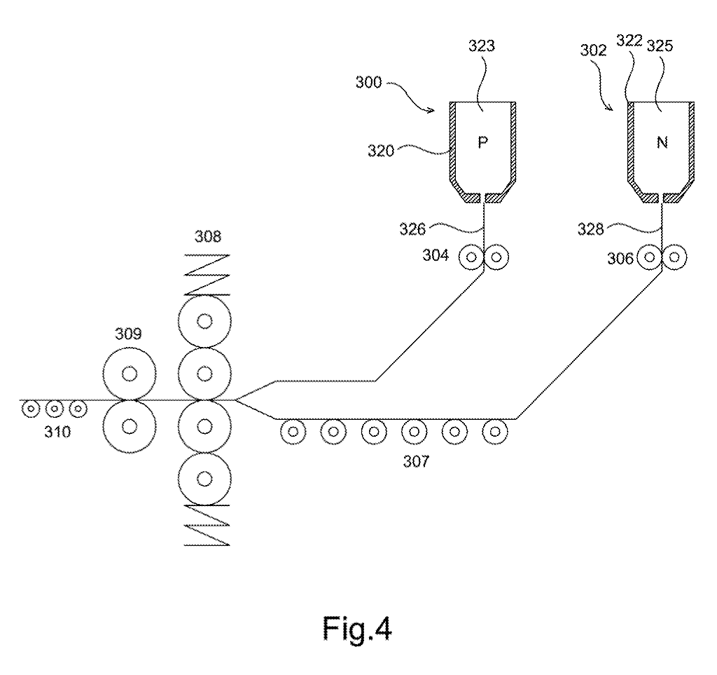

Referring to FIG. 4, it is another exemplary down draw process for forming a PN silicon thin film. The process of the PN silicon thin film may refer to the process of the PIN silicon thin film. Therefore, the detailed description is omitted.

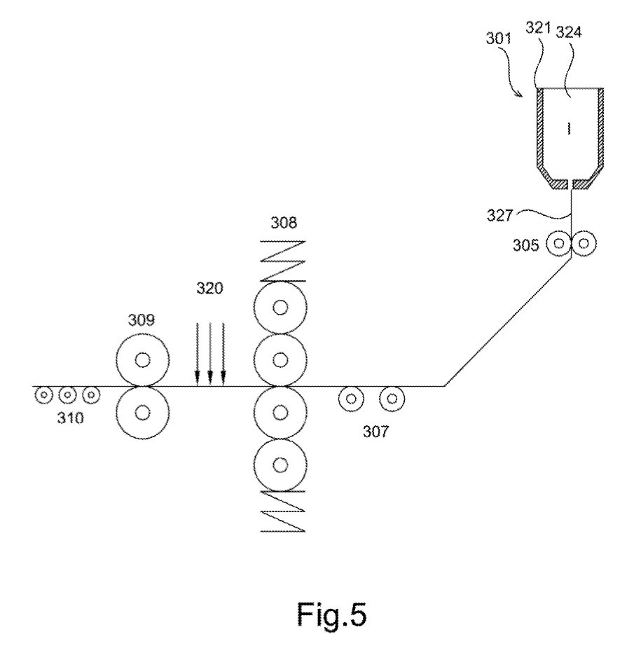

Referring to FIG. 5, it is another exemplary down draw process for forming a P-type or N-type silicon thin film. Similarly, the process of the P-type or N-type silicon thin film may refer to the process of the PIN silicon thin film. In addition, in this embodiment, it is further comprising a step of performing an ion implanting process of the silicon thin film to form a N or P type silicon thin film, which may be performed before creating a silicon thin film roll. The ion implanting process is performed by an ion beam 320 implanting into the silicon thin film as traditional silicon fab process.

The PN or PIN semiconductor thin film of the present invention may be applied for a solar cell device, for example silicon solar cells, amorphous silicon solar cells, Copper Indium Gallium Diselenide solar cells, Cadmium Telluride thin film photovoltaics, thin film silicon solar cells, or Dye-Sensitized solar cells.

In further embodiment, the PN or PIN semiconductor thin film may be stacked with at least one second PN or at least one PIN semiconductor thin film for further providing a wider energy hand to absorb solar rays.

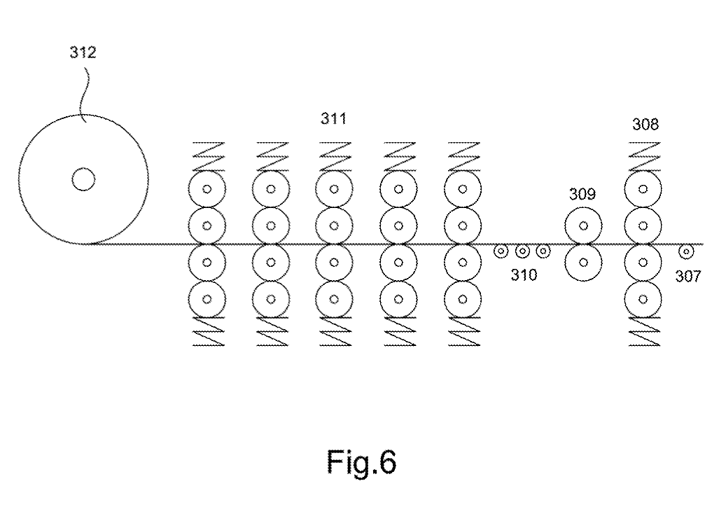

Referring to FIG. 6, it is an exemplary of forming a silicon thin film roll. After transporting over the roller 310, it is performing another roll press process which the silicon ribbon is further suitably pressed by a series of dual-side roll press 311 under suitable tension control for further attaching to form a silicon thin film or sheet, which thickness is about 1˜5 μm (micron). For example, the thickness of the silicon sheet may be controlled under 1 μm (micron). Subsequently, the silicon sheet is winged to be a silicon thin film roll 312 which has at least one silicon sheet, shown in FIG. 6. The silicon thin film roll may be a P-type, N-type, PN or PIN silicon thin film roll.

In a typical manufacturing environment of the present invention, the down draw process and the roll press process are performed under a high temperature (e.g. Transition Point temperature, or 800.degree. C.) and a vacuum situation to keep a stable physical state of the silicon ribbon.

Moreover, the PIN silicon sheet may be often produced by casting. In the casting technique, molten silicon in a crucible is gradually cooled from the bottom of the crucible for solidification of silicon, to obtain an ingot having long grains grown from the bottom of the crucible as its main body. This ingot is sliced into thin plates to obtain wafers available for the solar cells or the semiconductor devices.

As will be understood by persons skilled in the art, the foregoing preferred embodiment of the present invention illustrates the present invention rather than limiting the present invention. Having described the invention in connection with a preferred embodiment, modifications will be suggested to those skilled in the art. Thus, the invention is not to be limited to this embodiment, but rather the invention is intended to cover various modifications and similar arrangements included within the spirit and scope of the appended claims, the scope of which should be accorded the broadest interpretation, thereby encompassing all such modifications and similar structures. While the preferred embodiment of the invention has been illustrated and described, it will be appreciated that various changes can be made without departing from the spirit and scope of the invention.

What is claimed is:

1. A method of creating a PN semiconductor thin film, comprising the steps of:
providing a molten P-type semiconductor material and a molten N-type semiconductor material:
forming a P-type semiconductor ribbon and a N-type semiconductor ribbon of said molten P-type semiconductor material and said molten N-type semiconductor material;
joining said P-type semiconductor ribbon and said N-type semiconductor ribbon to form a PN semiconductor ribbon; and
performing a roll press process or a pressing process of said PN semiconductor ribbon to create said PN semiconductor thin film.

2. The method of claim 1, wherein said P-type semiconductor ribbon and said N-type semiconductor ribbon is formed by a down draw process or a casting process.

3. The method of claim 1, further comprising a step of performing a dual-side rolling process by dual-side rollers to said molten P-type semiconductor material and molten N-type semiconductor material.

4. The method of claim 1, wherein said molten P-type and N-type semiconductor material comprises P-type and N-type silicon or compound semiconductor, respectively.

5. The method of claim 1, wherein said joining may be performed by a set of alignment module established by XYθ stage and vision technology.

6. The method of claim 1, wherein said PN semiconductor thin film has an energy hand for facilitating absorbing solar rays.

7. The method of claim 1, further comprising a step of stacking said PN semiconductor thin film with at least one second PN or at least one PIN semiconductor thin film.

8. The method of claim 1, further comprising a step of performing a winging process of said PN semiconductor thin film such that a PN semiconductor thin film roll is created thereby.

9. A method of creating a PIN semiconductor thin film, comprising the steps of:
providing a molten P-type semiconductor material, a molten Intrinsic semiconductor material and a molten N-type semiconductor material;
forming a P-type semiconductor ribbon, a Intrinsic semiconductor ribbon and a N-type semiconductor ribbon of said molten P-type semiconductor material, said molten Intrinsic semiconductor material and said molten N-type semiconductor material;
joining said P-type semiconductor ribbon, said Intrinsic semiconductor ribbon and said N-type semiconductor ribbon to form a PIN semiconductor ribbon; and
performing a roll press process or a pressing process of said PIN semiconductor ribbon to create said PIN semiconductor thin film.

10. The method of claim 9, wherein said P-type semiconductor ribbon, said Intrinsic semiconductor ribbon and said N-type semiconductor ribbon is formed by a down draw process or a casting process.

11. The method of claim 9, further comprising a step of performing a dual-side rolling process by dual-side rollers to said molten P-type semiconductor material, said molten Intrinsic semiconductor material and said molten N-type semiconductor material.

12. The method of claim 9, wherein said molten P-type, Intrinsic and N-type semiconductor material comprises P-type, Intrinsic and N-type silicon or compound semiconductor, respectively.

13. The method, of claim 9, wherein said joining may be performed by a set of alignment module established by XYθ stage and vision technology.

14. The method of claim 9, wherein said PIN semiconductor thin film has an energy hand for facilitating absorbing solar rays.

15. The method of claim 9, further comprising a step of stacking said PIN semiconductor thin film with at least one second PIN or at least one PN semiconductor thin film.

16. The method of claim 9, further comprising a step of performing a winging process of said PIN semiconductor thin film such that a PIN semiconductor thin film roll is created thereby.

17. A method of creating a semiconductor thin film, comprising the steps of:
providing a molten semiconductor material;
forming a semiconductor ribbon of said molten semiconductor material;
performing a roll press process or a pressing process to said semiconductor ribbon to create a semiconductor thin film; and
performing an ion implanting process of said semiconductor thin film to form a N or P type semiconductor thin film.

18. The method of claim 17, wherein said semiconductor ribbon is formed by a down draw process or a casting process.

19. The method of claim 17, further comprising a step of performing a dual-side rolling process by dual-side rollers to said molten semiconductor material.

20. The method of claim 17, further comprising a step of performing a winging process of said N or P type semiconductor thin film such that a semiconductor thin film roll is created thereby.
